(19) United States
(12) Patent Application Publication
(10) Pub. No.: US 2011/0277839 A1
(43) Pub. Date: Nov. 17, 2011

(54) ED STRUCTURE AND SOLAR CELL INCLUDING THE SAME

(75) Inventors: Wei-Lun Chang, Yilan County (TW); Wen-Ching Sun, Taoyuan County (TW); Chung-Wen Lan, Taipei County (TW); Pei-Chen Yu, Hsinchu City (TW); Chia-Hua Chang, Taipei County (TW)

(73) Assignee: INDUSTRIAL TECHNOLOGY RESEARCH INSTITUTE, Hsinchu (TW)

(21) Appl. No.: 13/106,887

(22) Filed: May 13, 2011

(30) Foreign Application Priority Data
May 13, 2010 (TW) 99115273

(51) Int. Cl. H01L 31/0232; G02B 1/11

(52) U.S. Cl. 136/259; 359/601

(57) ABSTRACT

An anti-reflection coating (ARC) stacked structure including a first ARC layer and a second ARC layer is provided. The first ARC layer is a continuous layer and the second ARC layer, located over the first ARC layer, is formed in fractals. In addition, a solar cell including the ARC stacked structure is further provided.

### CROSS-REFERENCE TO RELATED APPLICATION

This application claims the priority benefit of Taiwan application serial no. 99115273, filed May 13, 2010. The entirety of the above-mentioned patent application is hereby incorporated by reference herein and made a part of this specification.

### TECHNICAL FIELD

The disclosure relates to an anti-reflection coating (ARC) stacked structure and a solar cell having the ARC stacked structure.

### BACKGROUND

An anti-reflection coating (ARC) layer is one of the most important factors for determining the efficiency of various photoelectric devices such as a solar cell. Nowadays, superior ARC layers are fabricated with nano-technology to obtain nano-textured layers.

The fabrication of traditional nano-textured layers is categorized into wet methods and dry methods, both of which are capable of reducing surface reflectivity. However, these methods have their problems. A typical example of using wet methods includes black cells. Although the fabrication cost can be greatly reduced, the nano-textured layers fabricated cannot adjust the thickness of oxide layers quantatively. Thus, effective mass production of the black cells is difficult due to the co-firing of the subsequent cell fabrication. Currently, the highest efficiency of solar cells by using wet methods is about 14% to 15%. In dry methods, on the other hand, expensive processes such as a photolithography process cannot be omitted. Even though high efficiency cells (with efficiency >20%) can be produced therefrom, the use of dry methods remains opposite to the trend of solar cells for pursuing low costs.

The newest nano-textured structures have features similar to graded composition layers and can function as ARC layers suitably. Nevertheless, the tilted angle must be changed during plating the films, which leads to plated films with limited areas and non-uniformity. As a consequence, the fabrication cost is high and mass production cannot be carried out. These drawbacks are not widely accepted by the industry.

### SUMMARY

The disclosure relates to an anti-reflection coating (ARC) stacked structure capable of reducing the reflectivity and enhancing the efficiency of a photoelectric device such as a solar cell.

The disclosure relates to an ARC stacked structure capable of controlling the thickness and the nano-structure using a simple normal plating method.

The disclosure relates to an ARC stacked structure having a fabrication process capable of operating in co-operation with a subsequent cell fabrication for mass production.

The disclosure relates to a solar cell with superior efficiency.

The disclosure relates to a method of fabricating an ARC layer without requiring the expensive photolithography process.

The disclosure relates to a solar cell including a photoelectric conversion structure and an anti-reflection coating stacked structure on the photoelectric conversion structure. The anti-reflection coating stacked structure includes a first ARC layer and a second ARC layer. The first ARC layer is located on the photoelectric conversion structure. The second ARC layer is formed in fractals and located on the first ARC layer.

The disclosure relates to an anti-reflection coating stacked structure. The anti-reflection coating stacked structure includes a first anti-reflection coating layer and a second anti-reflection coating layer. The first anti-reflection coating layer is a continuous layer. The second anti-reflection coating layer is formed in fractals and located on the first anti-reflection coating layer.

The ARC stacked structure of the disclosure is capable of reducing the reflectivity and enhancing the efficiency of a photoelectric device such as a solar cell.

The ARC stacked structure of the disclosure is capable of controlling the thickness and the nano-structure using a simple normal plating method.

The ARC stacked structure of the disclosure has a fabrication process compatible with subsequent steps of cell processes for mass production.

The disclosure relates to a solar cell with superior efficiency.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is schematic diagram illustrating an anti-reflection coating (ARC) stacked structure according to an exemplary embodiment.

FIG. 1A is partially enlarged diagrams of an area A in FIG. 1 illustrating an anti-reflection coating (ARC) stacked structure formed in dentritics.

FIG. 1B is also partially enlarged diagrams of the area A in FIG. 1 illustrating an anti-reflection coating (ARC) stacked structure formed in three-dimensional networks.

FIG. 2A is a schematic cross-sectional diagram illustrating a solar cell according to a first exemplary embodiment.

FIG. 2B is a schematic cross-sectional diagram illustrating a solar cell according to a second exemplary embodiment.

FIG. 2C is a schematic cross-sectional diagram illustrating a solar cell according to a third exemplary embodiment.

FIG. 3 is a diagram illustrating reflectivity versus wavelength curve for samples in Example 1 and Comparative Example 1.

FIG. 4 is a diagram illustrating quantum efficiency versus wavelength curve for samples in Example 1 and Comparative Example 1.

FIG. 5 is a diagram illustrating current density versus voltage curve for samples in Example 2 and Comparative Example 2.

FIG. 6 shows a SEM image of a sample in Example 2.

FIG. 7 shows a SEM image of a sample in Comparative Example 3.

### DESCRIPTION OF EMBODIMENTS

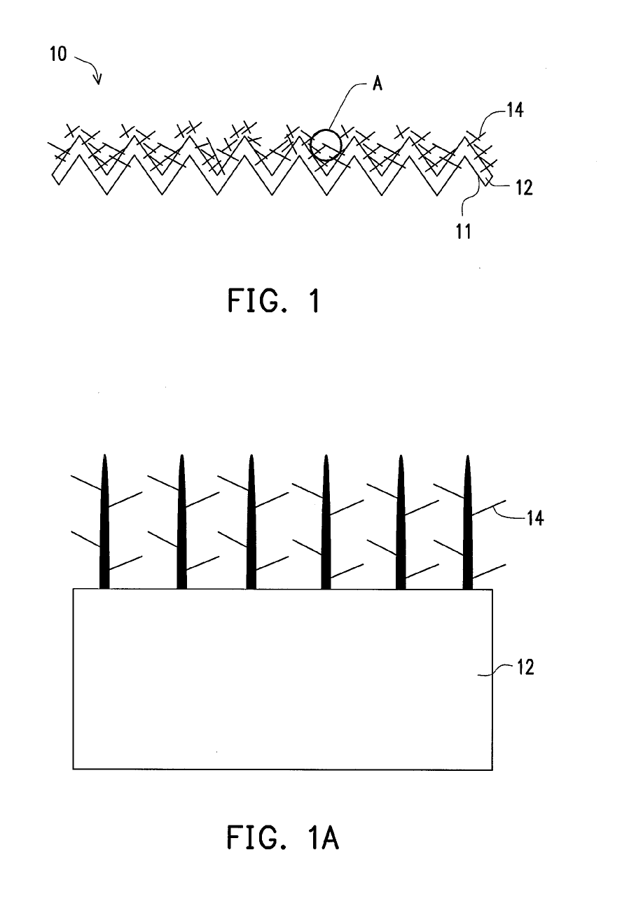

FIG. 1 is schematic diagram illustrating an anti-reflection coating (ARC) stacked structure according to an exemplary embodiment. FIG. 1A is partially enlarged diagrams of an area A in FIG. 1 illustrating an anti-reflection coating (ARC) stacked structure formed in dentritics. FIG. 1B is also partially enlarged diagrams of the area A in FIG. 1 illustrating an anti-reflection coating (ARC) stacked structure formed in three-dimensional networks.

Referring to FIG. 1, an ARC stacked structure 10 of an exemplary embodiment of the disclosure includes a first ARC layer 12 and a second ARC layer 14.

The first ARC layer 12 is a continuous layer. In an exemplary embodiment, the first ARC layer 12 is a continuous layer and located on a surface 11. The surface 11 can be a textured surface or a planar surface. The first ARC layer 12, for example, is located on a photoelectric conversion layer with a textured surface. Moreover, the first ARC layer 12 and the textured surface are substantially conformed. The textured surface has a shape of a pyramid or a slanted pyramid, or is an irregular surface with bumps. The material of the first ARC layer 12 comprises silicon dioxide, silicon nitride, aluminum oxide, zinc oxide, tin dioxide, or a combination thereof, for example. The first ARC layer 12 can be formed using a plasma enhanced chemical vapor deposition (PECVD) method, a metal-organic chemical vapor deposition (MOCVD) method, a physical vapor deposition (PVD) method, a sputtering deposition method, or an evaporation deposition method, for instance. The first ARC layer 12 has a thickness ranging from about 1 nm to about 100 nm, for example.

The second ARC layer 14 is located on the first ARC layer 12, and a conformation thereof is different from that of the first ARC layer 12. The second ARC layer 14 is formed in fractals, for example, dentritics, three-dimensional networks or a combination thereof as shown in FIGS. 1A, 1B, 1C, and 1D respectively. Each branch of the fractals has a size (diameter) in nanoscale or even smaller scales, about 1 nm to about 200 nm, for example, and the lengths thereof are about 1 nm to about 1000 nm. The second ARC layer 14 is made of a conductive material or a non-conductive material. That is, the second ARC layer 14 can be fabricated with indium tin oxide (ITO), zinc oxide (ZnO), silicon dioxide (SiO₂), tin dioxide (SnO₂), or a combination thereof, for example. The second ARC layer 14 is formed by, for instance, an electron beam evaporation deposition method or a sputtering deposition method. In one exemplary embodiment, the second ARC layer 14 is made of ITO and formed by utilizing the electron beam evaporation deposition method using an ITO target while adopting nitrogen and oxygen as reactive gases for deposition under a pressure ranging from about 10⁻⁶ torr to about 10⁻² torr, for example. In another exemplary embodiment, the second ARC layer 14 is made of ZnO and formed, for example, by utilizing the electron beam evaporation deposition method using a ZnO target while adopting nitrogen and oxygen as reactive gases for deposition under a pressure ranging from about 10⁻⁶ torr to about 10⁻² torr. In another exemplary embodiment, the second ARC layer 14 is made of SiO₂ and formed, for example, by utilizing the sputtering deposition method using a SiO₂ target while adopting argon and oxygen as reactive gases for deposition under a pressure ranging from about 10⁻⁸ torr to about 10⁻² torr. In another exemplary embodiment, the second ARC layer 14 is made of SnO₂ and formed, for example, by utilizing the electron beam evaporation deposition method using a SnO₂ target while adopting nitrogen and oxygen as reactive gases for deposition under a pressure ranging from about 10⁻⁶ torr to about 10⁻² torr. The second ARC layer 14 has a thickness ranging from about 1 nm to about 1000 nm, for example. The lengths of the fractal structure (such as a structure of dentritics or three-dimensional networks) of the second ARC layer 14 can be adjusted through controlling the duration of a nucleation time or a growth time during deposition. The second ARC layer 14 can be formed from a structure of dentritics and then become a denser structure such as three-dimensional networks by increasing the nucleation time and the growth time during deposition.

The second ARC layer 14 can precisely adjust the thickness and the nano-structure by depositing on the surface 11 (textured surface or planar surface) with a simple normal plating method with a tilted angle of 0, such that the second ARC layer 14 does not need to be plated by any tilting angle. The titled angle is an angle between a surface normal direction of the ARC stacked structure 10 and a normal direction of a target for providing source of the second ARC layer 14.

The ARC stacked structure of the exemplary embodiment in the disclosure has a fabrication process compatible with subsequent steps of cell processes for mass production.

The ARC stacked structure of the disclosure can be applied in various photoelectric devices, for example, solar cells, to enhance the performance of solar cells. A solar cell is used as an example in the following for illustration; however, the disclosure is not limited thereto.

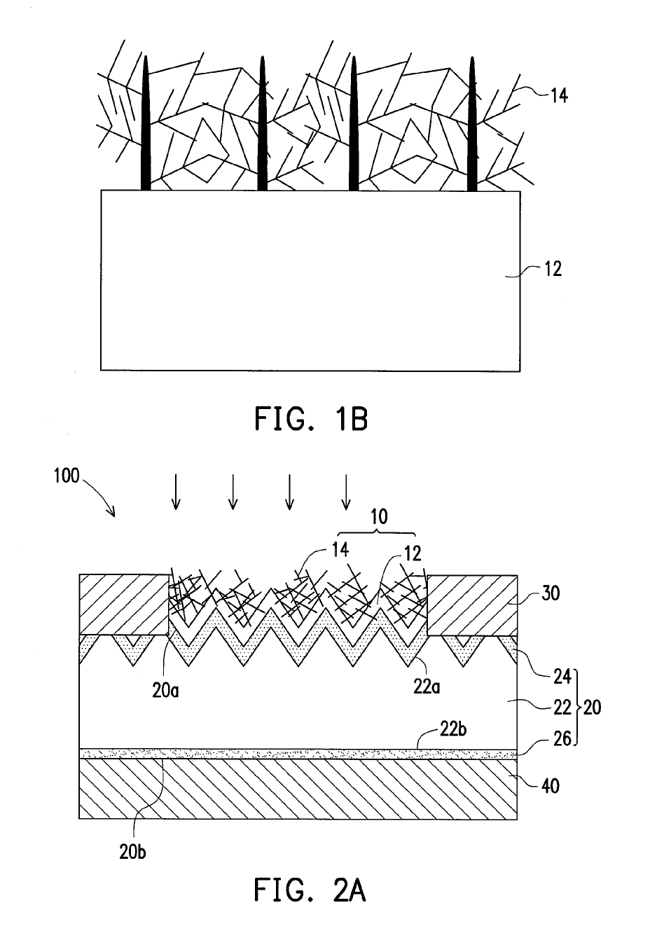

FIG. 2A is a schematic cross-sectional diagram illustrating a solar cell according to a first exemplary embodiment. FIG. 2B is a schematic cross-sectional diagram illustrating a solar cell according to a second exemplary embodiment. FIG. 2C is a schematic cross-sectional diagram illustrating a solar cell according to a third exemplary embodiment.

Referring to FIG. 2A, a solar cell 100 includes a photoelectric conversion structure 20, an ARC stacked structure 10, a first electrode 30, and a second electrode 40. The photoelectric conversion structure 20 includes a surface 20a and a surface 20b. In an embodiment, the surface 20a is a light receiving surface and has a textured surface, and the surface 20b is a non light receiving surface 20b. The ARC stacked structure 10a includes the first ARC layer 12 and the second ARC layer 14. The first ARC layer 12 is located on the surface 20a. The second ARC layer 14 is located on a portion of the first ARC layer 12 and formed in fractals. The materials, structures, and thicknesses of the first ARC layer 12 and the second ARC layer 14 are as those described above and thus omitted hereinafter. The first electrode 30 is located on other portion of the first ARC layer 12 and passes through the same. The first electrode 30 is electrically connected to the photoelectric conversion structure 20. The second electrode 40 is located on the surface 20b.

The photoelectric conversion structure 20 can be any known structure. In one exemplary embodiment, the solar cell 100 is a thin-film solar cell and the photoelectric conversion structure 20 includes a first type substrate 22, a second type doping layer 24, and a first type doping layer 26. The first type substrate 22 includes a surface 22a and a surface 22b. Herein, the surface 22a has the aforementioned textured surface, and the surface 22b has a planar surface. The second type doping layer 24 is located on the surface 22a. A surface of the second type doping layer 24 is the surface 20a, which is conformal to the surface 22a of the first type substrate 22. That is, the surface of the second type doping layer 24 also has a textured surface. A doping concentration of the second type doping layer 24 is higher than a doping concentration of the first type substrate 22. The first type doping layer 26 is located on the surface 22b of the first type substrate 22. A surface of the first type doping layer 26 is the surface 20b. A doping concentration of the first type doping layer 26 is higher than a doping concentration of the first type substrate 22. In one exemplary embodiment, the first type is a P type and the second type is an N type. In another exemplary embodiment, the first type is an N type and the second type is a P type. A dopant of the P type is boron or aluminum, for example, and a dopant of the N type is phosphorus or arsenic, for example. The substrate 22 is made of a semiconductor, for example, silicon.

In one exemplary embodiment, the first electrode 30 is formed in fingers. The first electrode 30 is made of a conductive material, for instance, a metal, an alloy, or a transparent conductive oxide. The metal is silver, aluminum, copper, tin, titanium, palladium, or gold, for example. The alloy is, for instance, silver-aluminum alloy or titanium-palladium-silver alloy. The transparent conductive material is, for example, ITO, ZnO, or SnO₂.

In one exemplary embodiment, the second electrode 40 is formed in plane. The second electrode 40 is made of a conductive material, for instance, a metal, an alloy, or a transparent conductive oxide. The metal is aluminum, copper, tin, titanium, palladium, or gold, for example. The alloy is, for instance, silver-aluminum alloy or titanium-palladium-aluminum alloy. The transparent conductive material is, for example, ITO, ZnO, or SnO₂.

The ARC stacked structure 10 formed on the surface 20a (light receiving surface) of the photoelectric conversion structure 20 are described in aforementioned embodiment, but not limited thereto. In another embodiment, the ARC stacked structure 10 can also be formed on the surface 20b of the photoelectric conversion structure 20 (shown on FIG. 2B). Or, the ARC stacked structure 10 or an ARC stacked structure 10′ can be formed respectively on the surface 20a and the surface 20b of the photoelectric conversion structure 20 (shown on FIG. 2C).

Referring to FIG. 2B, the photoelectric conversion structure 20 also includes the first type substrate 22, the second type doping layer 24, and the first type doping layer 26. Except configurations of the first type substrate 22, the second type doping layer 24, and the first type doping layer 26, the materials, the doping concentrations or the conductive types thereof are as those described above and thus omitted hereinafter. In the embodiment, the surface 22b has a textured surface, and the surface 22a can be a planar surface or a textured surface (not shown). The second type doping layer 24 is located on the surface 22a. A surface of the second type doping layer 24 is the surface 20a. The first type doping layer 26 is located on the surface 22b of the first type substrate 22. A surface of the first type doping layer 26 is the surface 20b, which is conformal to the surface 22b of the first type substrate 22. That is, the surface of the first type doping layer 26 also has a textured surface. A surface of the first type doping layer 26 is the surface 20b.

The first electrode 30 and the second electrode 40 are also located on the surface 20a and the surface 20b respectively. The materials of the first electrode 30 and the second electrode 40 are as those described above and thus omitted hereinafter. Both first electrode 30 and second electrode 40 have shapes that a light can pass through the photoelectric conversion structure 20. In an embodiment, the first electrode 30 and the second electrode 40 are formed in fingers and are symmetrical so that a light can pass through the photoelectric conversion structure 20. Thus, both surface 20a and surface 20b of the photoelectric conversion structure 20 are light receiving surfaces.

The ARC stacked structure 10′ is located on the surface 20b of the photoelectric conversion structure 20. The ARC stacked structure 10′ includes a first ARC layer 12′ and a second ARC layer 14′. The first ARC layer 12′ is located on the surface 20b. The second ARC layer 14′ is located on a portion of the first ARC layer 12′ and formed in fractals. The second electrode 40 is located on other portion of the first ARC layer 12′. The materials of the first ARC layer 12′ and the second ARC layer 14′ are as the first ARC layer 12 and the second ARC layer 14 described above and thus omitted hereinafter.

Referring to FIG. 2C, the photoelectric conversion structure 20 also includes the first type substrate 22, the second type doping layer 24, and the first type doping layer 26. Except configurations of the first type substrate 22, the second type doping layer 24, and the first type doping layer 26, the materials, the doping concentrations or the conductive types thereof are as those described above and thus omitted hereinafter. In the embodiment, the surface 22b and the surface 22a have textured surfaces. The second type doping layer 24 is located on the surface 22a, which is conformal to the surface 22a of the first type substrate 22. That is, the surface of the second type doping layer 24 also has a textured surface. A surface of the second type doping layer 24 is the surface 20a. The first type doping layer 26 is located on the surface 22b of the first type substrate 22. A surface of the first type doping layer 26 is conformal to the surface 22b of the first type substrate 22. That is, the surface of the first type doping layer 26 also has a textured surface. A surface of the first type doping layer 26 is the surface 20b.

The first electrode 30 and the second electrode 40 are also located on the surface 20a and the surface 20b respectively. The materials of the first electrode 30 and the second electrode 40 are as those described above and thus omitted hereinafter. Both first electrode 30 and second electrode 40 have shapes that a light can pass through the photoelectric conversion structure 20. In an embodiment, the first electrode 30 and the second electrode 40 are formed in fingers and are symmetrical so that a light can pass through the photoelectric conversion structure 20. Thus, both surface 20a and surface 20b are light receiving surfaces.

The ARC stacked structures 10 and 10′ are located on the surfaces 20a and 20b of the photoelectric conversion structure 20 respectively. The ARC stacked structure 10 includes the first ARC layer 12 and the second ARC layer 14. The first ARC layer 12 is located on the surface 20a. The second ARC layer 14 is located on a portion of the first ARC layer 12 and formed in fractals. The first electrode 30 is located on other portion of the first ARC layer 12. The ARC stacked structure 10′ includes the first ARC layer 12′ and the second ARC layer 14′. The first ARC layer 12′ is located on the surface 20b. The second ARC layer 14′ is located on a portion of the first ARC layer 12′ and formed in fractals. The second electrode 40 is located on other portion of the first ARC layer 12. The materials of the first ARC layers 12 and 12′, and the second ARC layers 14 and 14′ are as those described above and thus omitted hereinafter.

### Example 1

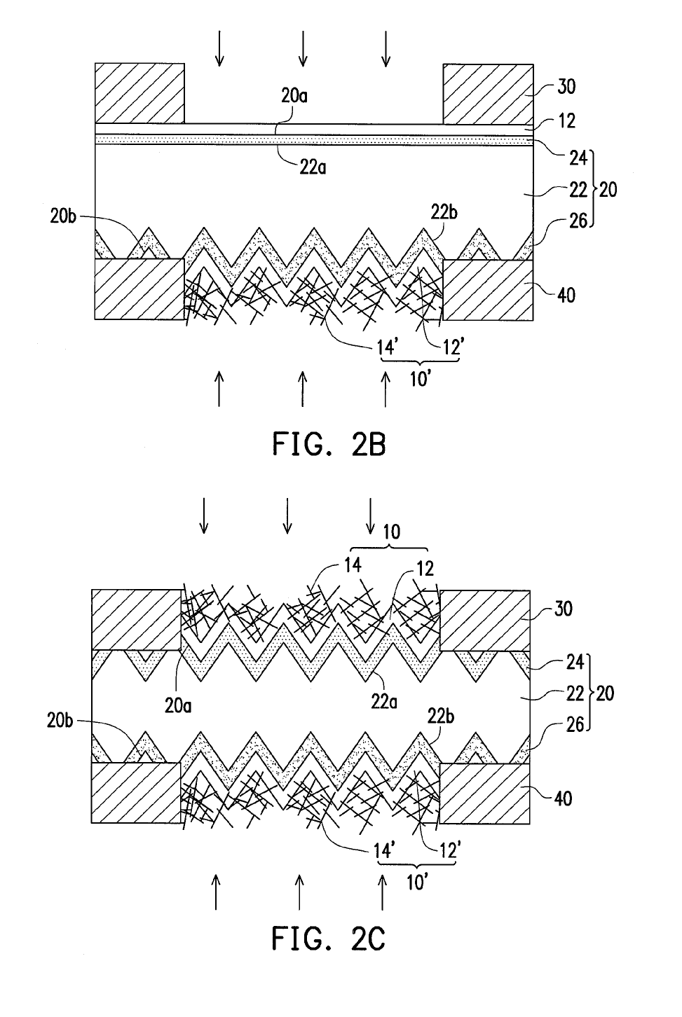

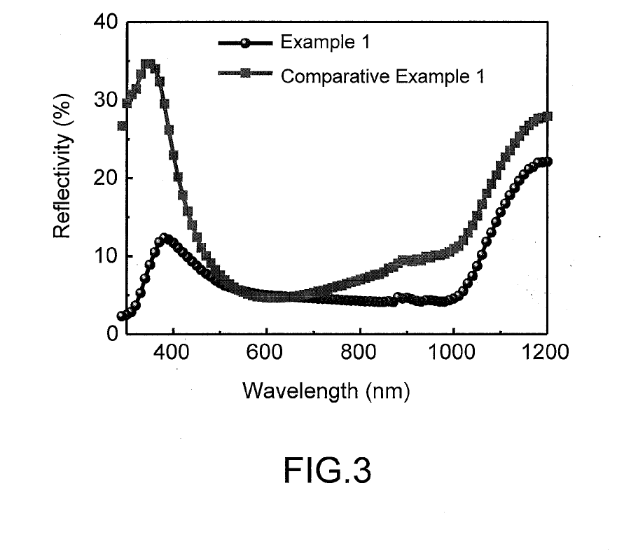

A surface texturization process is performed to a front surface of a P type monocrystalline silicon substrate using potassium hydroxide to generate a pyramid structure. Thereafter, POCl₃ is flowed into a high temperature furnace tube for a phosphorus diffusion to form a PN junction. A silicon nitride layer (SiNₓ) is then plated on the front surface of the P type monocrystalline silicon substrate as a first ARC layer with the plasma enhanced CVD method. Afterwards, ITO nano-dentritics are formed on the SiNₓ layer on the front surface of the substrate as a second ARC layer. A scanning electron microscope (SEM) is used to observe a conformation of the fabricated sample and measure the reflectivity and the quantum efficiency versus wavelength of an incident light for the fabricated sample as shown in FIGS. 3 and 4.

### Comparative Example 1

A sample is fabricated in a manner similar to that in Example 1. However, ITO nano-dentritics acting as the second ARC layer are not formed on the SiNₓ layer.

### Example 2

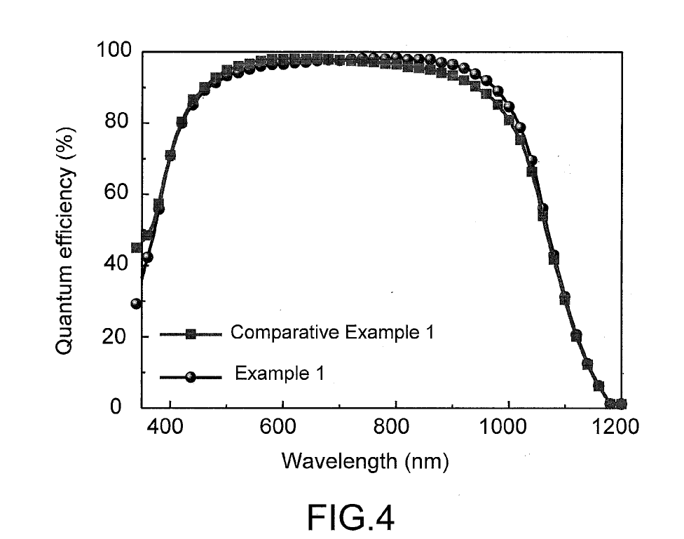

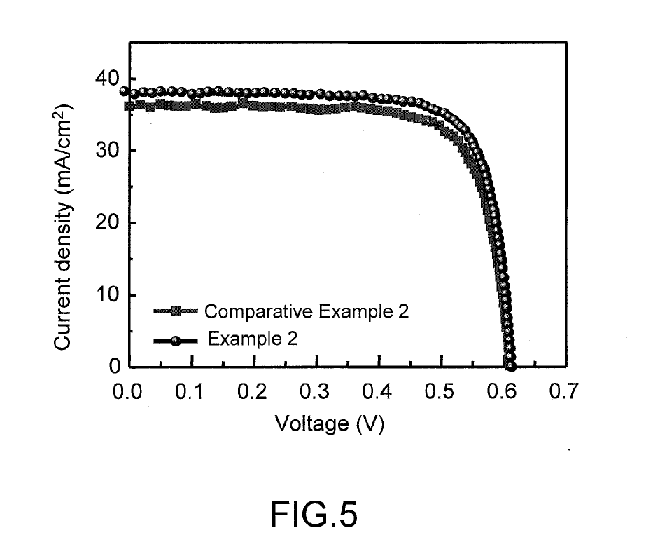

The same surface texturization process described in Example 1 is performed to a front surface of a P type monocrystalline silicon substrate to generate a pyramid structure. Thereafter, POCl₃ is flowed into a high temperature furnace tube for a phosphorus diffusion to form a PN junction. A SiNₓ layer is then plated on the front surface of the P type monocrystalline silicon substrate as a first ARC layer. Afterwards, a silver paste and an aluminum paste adopted as electrodes are respectively formed on the front surface and a back surface of the P type monocrystalline silicon substrate by screen printing. Later, ITO nano-dentritics are formed on the SiNₓ layer on the front surface of the substrate as a second ARC layer. A co-firing process is then preceded. An electrical characteristic measurement (current density versus voltage) is performed, and the results thereof are illustrated in Table 1 and FIG. 5. The SEM image of this sample is shown in FIG. 6.

### Comparative Example 2

A sample is fabricated in a manner similar to that described in Example 2, but ITO nano-dentritics are not formed on the SiNₓ layer on the front surface of the substrate. An electrical characteristic measurement (current density versus voltage) is performed, and the results thereof are illustrated in Table 1 and FIG. 5.

### Comparative Example 3

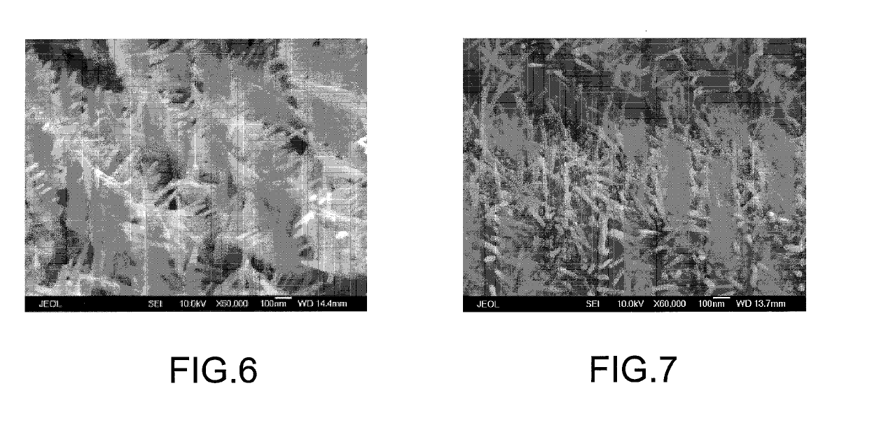

A sample is fabricated in a manner similar to that described in Example 2, but ITO nano-rods are instead of ITO nano-dentritics. An electrical characteristic measurement is performed, and the results thereof are illustrated in Table 2. The SEM image of this sample is shown in FIG. 7.

TABLE 1

| | | Comparative | |
|---|---|---|---|
| | | Example 2 | |
| | Example 2 | without | |
| | with nano-dentritics | nano-dentritics | Increment |
| Current density | 37.36 | 35.84 | 1.52 |
| (mA/cm²) | | | |
| Open-circuit voltage | 0.612 | 0.610 | 0.002 |
| (V) | | | |
| Filling factor | 75.13 | 73.45 | 1.68 |
| (%) | | | |
| Efficiency | 17.18 | 16.08 | 1.1 |
| (%) | | | |

TABLE 2

| | | Comparative | |
|---|---|---|---|
| | Example 2 | Example 3 | |
| | with nano-dentritics | with nano-rods | Increment |
| Current density | 37.36 | 35.74 | 1.62 |
| (mA/cm²) | | | |
| Open-circuit voltage | 0.612 | 0.610 | 0.002 |
| (V) | | | |
| Filling factor | 75.13 | 73.20 | 1.93 |
| (%) | | | |
| Efficiency | 17.18 | 15.97 | 1.21 |
| (%) | | | |

As shown from the SEM results, the ITO in Example 1 is formed in nano-dentritics, and short branches with a length of about 655 nm can be observed on the surface of the nano-pillar structure.

The results in FIG. 3 show that the sample having the ITO nano-dentritics as the second ARC layer (Example 1) has a reflectivity of R<12% at a visible wavelength of 350 nm; a lower reflectivity of R<6% at a wavelength ranging from 400 nm to 1100 nm. The results illustrate that the sample having the ITO nano-dentritics as the second ARC layer has a higher reflectivity comparing to the sample merely using the SiNx layer as the ARC layer (Comparative Example 1).

From the results in FIG. 4, it is shown that the sample having the ITO nano-dentritics as the second ARC layer (Example 1) has a better quantum efficiency comparing to the sample merely using the SiNx layer as the ARC layer (Comparative Example 1).

From the results in FIG. 5, it is shown that a current density Jsc and a quantum efficiency of the sample having the ITO nano-dentritics as the second ARC layer (Example 2) have respectively increased by 1.52 mA/cm² and 1.1% comparing to those of the sample merely using the SiNx layer as the ARC layer (Comparative Example 2).

From the results in FIGS. 6 and 7, ITO nano-dentritics are formed in Example 2, whereas ITO nano-rods are formed in Comparative Example 3. Further, according to Table 2, the sample with the ITO nano-dentritics of Example 2 has batter electrical characteristics than the sample with the ITO nano-rods of Comparative Example 3.

In summary, the ARC stacked structure with nano-fractals of the disclosure is capable of reducing the reflectivity and enhancing the efficiency of an photoelectric device such as a solar cell. In addition, the ARC stacked structure with nano-fractals of the disclosure can precisely adjust the thickness and the nano-fractals by utilizing a simple normal plating method, such that the film does not need to be plated by any tilting angle. Moreover, the costly photolithography process can be omitted so as to reduce fabrication cost. Furthermore, the ARC stacked structure with nano-fractals of the disclosure has a fabrication process capable of operating in co-operation with a subsequent solar cell fabrication for mass production. Consequently, the solar cell has superior efficiency and the fabrication cost can be greatly reduced. The solar cell can thus be more competitive in the market. Also, the ARC stacked structure with nano-fractals of the disclosure has the potential to be applied in solar cells of thin-film, MWT, EWT, IBC, or HIT for greatly enhancing the efficiency.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A solar cell, comprising:
a photoelectric conversion structure; and
an anti-reflection coating stacked structure located on the photoelectric conversion structure, comprising:
a first anti-reflection coating layer, located on the photoelectric conversion structure; and
a second anti-reflection coating layer, located on a portion of the first anti-reflection coating layer and being formed in fractals.

2. The solar cell as claimed in claim 1, wherein the photoelectric conversion structure comprises a first surface and a second surface, and the anti-reflection coating stacked structure is located on the first surface or the second surface or a combination thereof.

3. The solar cell as claimed in claim 2, wherein the first surface or the second surface or the combination thereof has a textured surface.

4. The solar cell as claimed in claim 1, further comprising a first electrode and a second electrode so that the photoelectric conversion structure sandwiched therebetween.

5. The solar cell as claimed in claim 1, wherein the photoelectric conversion structure comprises:
a first type substrate comprising a first surface and a second surface;
a second type doping layer, located on the first surface; and
a first type doping layer, located on the second surface, a doping concentration of the first type doping layer being higher than a doping concentration of the first type substrate.

6. The solar cell as claimed in claim 1, wherein a material of the second anti-reflection coating layer comprises a conductive material.

7. The solar cell as claimed in claim 1, wherein a material of the second anti-reflection coating layer comprises a non-conductive material.

8. The solar cell as claimed in claim 1, wherein a material of the second anti-reflection coating layer comprises indium tin oxide, zinc oxide, silicon dioxide, tin dioxide, or a combination thereof.

9. The solar cell as claimed in claim 1, wherein the fractals of the second anti-reflection coating layer comprise dentritics, three-dimensional networks, or a combination thereof.

10. The solar cell as claimed in claim 1, wherein a thickness of the second anti-reflection coating layer ranges from about 1 nm to about 1000 nm.

11. The solar cell as claimed in claim 1, wherein a material of the first anti-reflection coating layer comprises silicon dioxide, silicon nitride, aluminum oxide, zinc oxide, tin dioxide, or a combination thereof.

12. The solar cell as claimed in claim 1, wherein a conformation of the first anti-reflection coating layer is a continuous layer.

13. An anti-reflection coating stacked structure, comprising:
a first anti-reflection coating layer; and
a second anti-reflection coating layer, located on the first anti-reflection coating layer,
wherein the first anti-reflection coating layer is a continuous layer and the second anti-reflection coating layer is formed in fractals.

14. The anti-reflection coating stacked structure as claimed in claim 13, wherein the first anti-reflection coating layer is located on a textured surface and substantially conformal to the textured surface.

15. The anti-reflection coating stacked structure as claimed in claim 13, wherein a material of the second anti-reflection coating layer comprises a conductive material.

16. The anti-reflection coating stacked structure as claimed in claim 13, wherein a material of the second anti-reflection coating layer comprises a non-conductive material.

17. The anti-reflection coating stacked structure as claimed in claim 13, wherein a material of the second anti-reflection coating layer comprises indium tin oxide, zinc oxide, silicon dioxide, tin dioxide, or a combination thereof.

18. The anti-reflection coating stacked structure as claimed in claim 13, wherein the fractals of the second anti-reflection coating layer comprise dentritics, three-dimensional networks, or a combination thereof.

19. The anti-reflection coating stacked structure as claimed in claim 13, wherein a thickness of the second anti-reflection coating layer ranges from about 1 nm to about 1000 nm.

20. The anti-reflection coating stacked structure as claimed in claim 13, wherein a material of the first anti-reflection coating layer comprises silicon dioxide, silicon nitride, aluminum oxide, zinc oxide, tin dioxide, or a combination thereof.
